(19) United States
(12) Patent Application Publication
(10) Pub. No.: US 2003/0143469 A1
(43) Pub. Date: Jul. 31, 2003

(54) Grade tie bar only (GTO) and graded grade tie bar only (GGTO) aperture masks

(76) Inventors: Thomas R. Sage, Endwell, NY (US); Lance M. Benjamin, LaFayette, NY (US); Jeffrey Z. Wang, Jamesville, NY (US); Leo B. Kriksunov, Ithaca, NY (US)

Correspondence Address: INSKEEP, James W., Oppenheimer Wolff & Donnelly LLP, Suite 700, 840 Newport Center Drive, Newport Beach, CA, 92660, US

(21) Appl. No.: 10/307,641

(22) Filed: Dec. 2, 2002

Related U.S. Application Data
(60) Provisional application No. 60/334,212, filed on Nov. 30, 2001.
(60) Provisional application No. 60/411,258, filed on Sep. 16, 2002.

(51) Int. Cl. G03F 9/00

(52) U.S. Cl. 430/5

(57) ABSTRACT

A mask useable to direct an electron beam having a cone side and a grade side. The cone side includes a plurality of troughs that extend partially into the mask but do not extend to the grade side. Apertures are formed in the bottoms of the troughs that extend through to the grade side. The apertures are separated by both actual and virtual tie bars. In a preferred embodiment, some of the virtual tie bars extend from the grade side, through the trough to the cone side. The occurrence of these cone side virtual tie bars varies in concentration across the extent of the mask such that the concentration is heavy in areas where clipping is desired, and light in areas where clipping is not desired. In another preferred embodiment, the size, shape and location of the cone side virtual tie bars vary across the extent of the mask to accommodate for the angle of the electron beam travel and the necessity for localized clipping.

### CROSS REFERENCE TO RELATED APPLICATIONS

This application claims priority from U.S. Provisional Patent Application Ser. No. 60/334,212 filed Nov. 30, 2001, and U.S. Provisional Patent Application No. 60/411258 filed on Sep. 16, 2002.

### BACKGROUND OF THE INVENTION

Cathode ray tubes (hereinafter “CRTs”), such as those used in televisions, oscilloscopes, and computer screens, operate by shooting electron beams from an electron gun toward a screen coated with a layer of phosphor or, in the case of color screens, three different color-emitting phosphors. Between the screen and the gun, lies a metal mask used to direct the electron beam, thereby providing a control mechanism for guiding the beam to strike a desired place on the screen. In order to allow the electron beam to pass through the mask and strike the screen, the mask is constructed and arranged with hundreds of troughs, usually arranged in vertical columns. The troughs are substantially open on the screen (or “cone”) side of the mask and extend partially through the thickness of the mask but stop short of the gun (or “grade”) side of the mask. At the deepest portion of the troughs are defined hundreds of thousands of apertures that extend through to the grade side of the mask. These apertures allow the electron beams to pass through the mask and strike the screen.

By thinking of the apertures as tiny, yet three-dimensional, tunnels one quickly realizes that those beams directed toward the edges of the screen are likely to strike the walls of the apertures due to the angular difference between the direction of travel of the electron beam and the direction the aperture extends. The troughs are formed as an attempt to shorten the length of the tunnels, by making the opening on the cone side larger than the opening on the grade side.

Additionally, the length of the troughs are typically interrupted by a plurality of bridge like supports known as “tie bars”. The tie bars add rigidity and strength to the mask and provide beam control in a vertical direction. For purposes of this application, tie bars are distinguished by being either grade side or cone side tie bars and by being either actual or virtual tie bars. Reference is made to FIGS. 1a and 1b for explanation.

FIGS. 1a shows a mask 1 with a cone side 2 and a grade side 3. A plurality of troughs 4 are formed in the cone side 2 and are interrupted by actual tie bars 5, which span the troughs 4, and virtual tie bars 6, which extend partially across but do not span the troughs 4. Virtual tie bars are especially prevalent in semi-tension masks. At the bottom of the troughs 4, the mask 1 defines a plurality of apertures 7, through which the electron beam (not shown) may pass.

FIG. 1b shows the grade side 3 of mask 1. It can be seen that the apertures 7 extend through the grade side 3 and are separated by actual tie bars 8 and virtual tie bars 9. As stated above, a distinction is drawn between actual tie bars 5 on the cone side 2 and actual tie bars 8 on the grade side 3 as well as between virtual tie bars 7 on the cone side 2 and virtual tie bars 9 on the grade side 3.

Again, tie bars generally function to provide vertical control of the electron beam, and, especially in the case of actual tie bars, add rigidity and strength to the mask. However, the tie bars on the grade side of the mask are frequently sufficient to accomplish both of these functions. The tie bars on the cone side of the mask add rigidity but often interfere with the electron beam.

There is a need for a mask that minimizes, selectively eliminates, or completely eliminates electron beam interference without adversely compromising the structural integrity of the mask.

### BRIEF SUMMARY OF THE INVENTION

The grade tie bar only (“GTO”) concept of the present invention is premised on the idea of reducing or even eliminating the number of tie bars that are present on the screen side of the aperture mask. The result is a mask where the tie bars are primarily or solely on the grade side of the mask.

In a first embodiment of the GTO concept, actual tie bars only are present on the grade side of the mask and no actual (nor any virtual) tie bars are present on the cone side of the mask. Such a design increases the electron beam transmission through the apertures, especially at the edges of the tube. This design also allows for the use of a thicker aperture mask material for both standard formed mask and semi-tension masks than currently used, while maintaining equivalent or improved brightness, thereby improving microphonic and magnetic performance in the tube.

In a second embodiment of the GTO concept, the grade side of the mask is comprised of both actual tie bars and virtual tie bars and no actual nor virtual tie bars are present on the cone side of the mask. This design enhances the advantages in beam transmission that are known to be achieved through the use of virtual tie bars. For example, the design makes it easier to form desirable shapes of virtual tie bars, particularly along the minor axis and in the diagonal corners. Furthermore, this design leads to improved uniformity of both virtual tie bar shape and beam clearance through the mask, especially at the outer periphery. This results in improved overall visual uniformity of the tube. Finally, the design leads to the formation of improved slot shape, thus improving the squareness of the electron beam as it strikes the tube surface.

In a third embodiment of the GTO concept, the grade side of the mask is comprised of both actual tie bars and virtual tie bars. In those areas of the cone side that align with actual tie bars on the grade side, there exist corresponding cone side actual tie bars. In those areas of the cone side that align with virtual tie bars on the grade side, however, there are no cone side tie bars (neither actual nor virtual).

The mask of this third embodiment similarly offers advantages in beam transmission performance and uniformity but may have greater strength than the mask of the second embodiment. The greater strength may result from the presence of a cone side actual tie bar in the area that aligns with a grade side actual tie bar that, in turn, leads to the presence of greater material in this region. The greater amount of material results in the mask having greater capability to support a load or tension that may be applied to the mask, and reduces the tendency for damage due to handling.

In a fourth embodiment of the GTO concept, the grade side of the mask again is comprised of both actual tie bars and virtual tie bars. In those areas of the cone side that align with actual tie bars on the grade side, there are no cone side tie bars (neither actual nor virtual). In this respect, this fourth embodiment is similar to the previously described second embodiment. However, the areas of the cone side that align with virtual tie bars on the grade side are treated differently from those of the second embodiment.

We first discuss the center region of the mask. In those center areas of the cone side that align with virtual tie bars on the grade side, there are no cone side tie bars (neither actual nor virtual).

We next discuss the extreme region along the x-axis of the mask and the diagonal corners of the mask. In those extreme x-axis and diagonal corner areas of the cone side that align with virtual tie bars on the grade side, there exist corresponding virtual tie bars.

We next discuss the y-axis areas of the mask. In those y-axis areas of the cone side that align with the virtual tie bars on the grade side, there are no cone side tie bars (neither actual nor virtual).

Finally, there exist transition zones on the cone side of the mask between those areas that do not have cone side tie bars (neither virtual nor actual) and those areas that have virtual tie bars. More specifically, there exist transition zones on the cone side of the mask from (1) the center of the mask (no tie bars) to the extreme x-axis and diagonal corners of the mask (virtual tie bars) and (2) from the end of the y-axis (no tie bars) to the diagonal corners (virtual tie bars). These transition zones may be based on x and y coordinates as well as the angle of electron beam transmission through the mask.

This fourth embodiment may be referred to as a graded grade tie bar only (GGTO) design due to the “graded” nature of the mask that results from the use of the transition zones. This design leads to the formation of improved and more precise shapes of the virtual tie bar in those areas where there are no aligning cone side virtual tie bars, namely, in the center of the mask and along the y-axis. The beam clearance through the virtual tie bars in these areas is also improved.

The design of the fourth embodiment also provides a way to “clip” the electron beam at locations where it is desirable to do so, namely, along the x-axis and along the diagonal axis of the mask. In other words, the presence of cone side virtual tie bars at the extreme x-axis area and at the diagonal corners of the mask, and the presence of transition zones there between, serves as a mechanism to “clip” the beam in these locations thus reducing or eliminating any electron beam passage through the virtual tie bar slot. This design improves the virtual tie bar shape and resultant electron beam shape at the center section of the mask and along the y-axis, while maintaining the capability to “clip” the electron beam passage through the virtual tie bars in the vicinity of the major axis and diagonal corners of the mask.

In a fifth embodiment, the design and advantages are very similar to the fourth embodiment except that in areas of the grade side that have actual tie bars, there are corresponding actual tie bars on the cone side. As explained in embodiment three, the cone side actual tie bars may improve the overall strength of the mask and reduce damage during handling.

By way of example only, included herewith as FIGS. 8 and 9 are photographs of the beam shape as it passes through the slot at beam angle. These figures demonstrate a prior art, non-GTO design (FIG. 8) and a GTO design in accordance with the invention, in this case the third embodiment of the invention (FIG. 9). On the left side of each of these FIGS. are a series of photographs of various locations (as determined by x-y coordinates) on a mask as viewed from the cone side of the mask. On the right side of each of these Exhibits are a series of photographs showing the result of an electron beam passing through the aperture shown in the corresponding left column picture.

As can be seen in the left photographs of FIG. 8, the prior art mask is comprised of aligning virtual tie bars both on the grade and the cone side. As can be seen in the left photographs of FIG. 9, the mask of this embodiment of the present invention is comprised of virtual tie bars only on the grade side (no virtual or actual tie bars on the cone side that line up with the grade side virtual tie bars).

The advantages of the present invention are readily apparent by comparing the right photographs in FIG. 8 with the right photographs of FIG. 9. The right photographs of FIG. 8 show that in the area of the virtual tie bars there is an inconsistent transmission of the electron beam. In fact, in some cases the beam transmission in the area of the virtual tie bar has been completely obstructed (e.g., the photograph of the mask at X=250, beam angle=45 degrees). In contrast, the right photographs of FIG. 9 show a very consistent transmission of the electron beam in the area of the virtual tie bars. Moreover, the transmission is shown to be very crisp and square as compared to the photographs of FIG. 8.

FIG. 10 depicts a series of photographs showing cross-sectional views through slots on an aperture mask in accordance with one embodiment of the present invention.

### BRIEF DESCRIPTION OF THE DRAWINGS

FIG. 1a is a perspective view of the cone side of a mask of the prior art;

FIG. 1b is a perspective view of the grade side of the mask of FIG. 1a;

FIG. 2a is a perspective view of one of the five basic types of tie bar configurations of the present invention;

FIG. 2b is a perspective view of one of the five basic types of tie bar configurations of the present invention;

FIG. 2c is a perspective view of one of the five basic types of tie bar configurations of the present invention;

FIG. 2d is a perspective view of one of the five basic types of tie bar configurations of the present invention;

FIG. 2e is a perspective view of one of the five basic types of tie bar configurations of the present invention;

FIG. 3 is a map of a preferred embodiment of the mask of the present invention;

FIG. 4 is a map of another preferred embodiment of the mask of the present invention;

FIG. 5 is a map of another preferred embodiment of the mask of the present invention;

FIG. 6 is a map of another preferred embodiment of the mask of the present invention;

FIG. 7 is a map of another preferred embodiment of the mask of the present invention;

FIGS. 8a and 8b are photographs of an electron beam as it passes through a non-GTO mask of the prior art at beam angle;

FIGS. 9a and 9b are photographs of the electron beam as it passes through a GTO mask of the present invention at beam angle;

FIG. 10 is a series of photographs showing cross-sectional views through slots on an aperture mask in accordance with one embodiment of the present invention; and,

FIG. 11 is a map of another preferred embodiment of the mask of the present invention.

FIG. 12 is a series of photographs showing the transitioning shape and size of the virtual tie bars of the preferred embodiment mapped in FIG. 11.

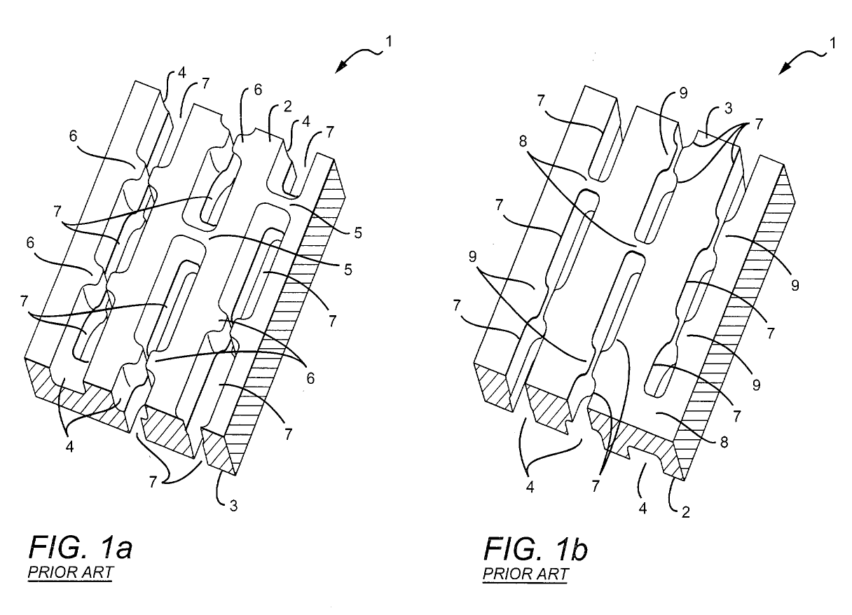

### DETAILED DESCRIPTION OF THE INVENTION

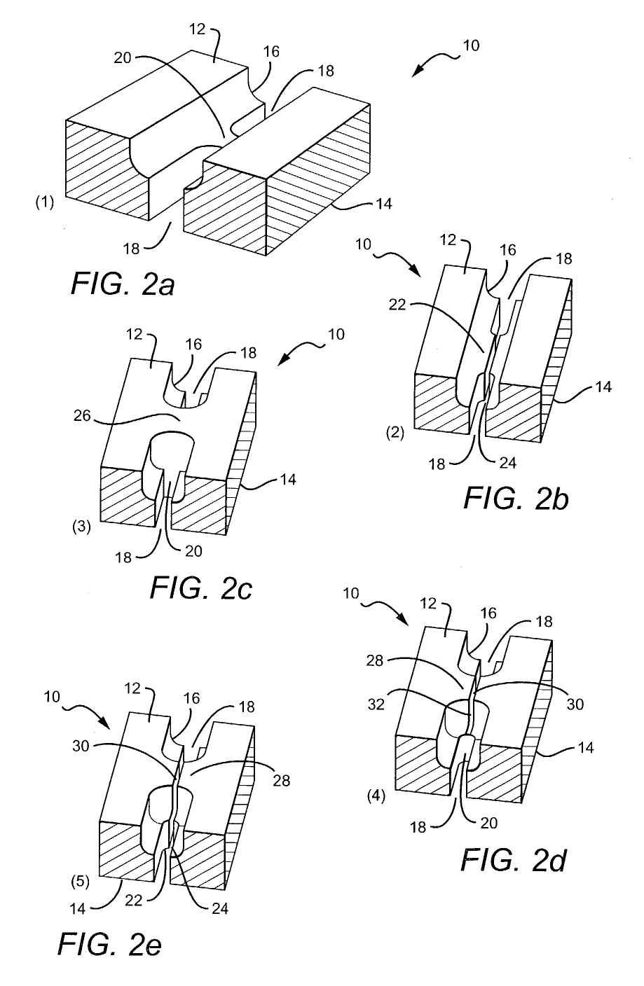

Referring now to FIG. 2a-e, there are shown five sections (1), (2), (3), (4) and (5), of mask having various tie bar configurations. Explanation will first be made pertaining to the construction of each of these configurations. Later, the masks of the present invention will be discussed referring to these five sections. This convention will allow maps to be drawn representative of masks having one or more of these configurations in various areas of the mask. All configurations (1)-(5) show a section of a mask 10 having a cone side 12 and a grade side 14. A trough 16 is formed in the cone side 12, but does not extend through to the grade side 14. At the bottom of the trough 16, two or more apertures 18 are formed that extend through to the grade side 14.

Referring now to configuration (1), it can be seen that a pair of apertures 18 are separated by a solid, actual tie bar 20 formed in the grade side 14 of the mask 10. For purposes of clarity, such actual tie bars 20 shall hereinafter be referred to as grade side actual tie bars 20. In configuration (1), there is no tie bar (neither virtual nor actual) formed in the cone side 12 that corresponds to the grade side actual tie bar 20.

Configuration (2) is somewhat similar to configuration (1) except that a pair of apertures 18 are separated and defined by a virtual tie bar 22 formed in the grade side 14 (hereinafter “grade side virtual tie bar 22”). The grade side virtual tie bar 22 differs from the grade side actual tie bar 20 of configuration (1) due to a gap 24 formed in the grade side virtual tie bar 22. In configuration (2), there is no tie bar (neither virtual nor actual) formed in the cone side 12 that corresponds to the grade side virtual tie bar 22.

Configuration (3), like configuration (1), has a pair of apertures 18 that are separated by a grade side actual tie bar 20. However, configuration (3) also has a cone side actual tie bar 26 that corresponds to the grade side actual tie bar 20. The cone side actual tie bar 26 is relatively flush with the surface of the cone side 12 of the mask 10 and spans the entire trough 16 formed in the cone side 12. The cone side actual tie bar 26 is said to “correspond” to the grade side actual tie bar 20 because it is relatively close to having the same location in terms of position on the mask 10, and differs in location only based on cone side 12 or grade side 14. It will be seen, however, that the cone side actual tie bar 26 may be slightly offset from the grade side actual tie bar 20, vertically, horizontally, or both, and still be considered to be “corresponding” to the grade side actual tie bar 20. The slight offset is useful to enhance beam clearance in some portions of the mask 10.

Configuration (4) is similar to configuration (3) in that configuration (4) also has a grade side actual tie bar 20 and a corresponding tie bar on the cone side 12. However, configuration (4) has a cone side virtual tie bar 28 that corresponds to the grade side actual tie bar 20. The cone side virtual tie bar 28 is distinguished by a gap 30 that extends from the surface of the cone side 12 to the inner most limit 32 of the grade side actual tie bar 20.

Configuration (5) is similar to configuration (4) in that configuration (5) has a cone side virtual tie bar 28. However, the cone side virtual tie bar 28 of configuration (5) corresponds to a grade side virtual tie bar 22 rather than a grade side actual tie bar 20. The gap 30 of the cone side virtual tie bar 28 is shown as being aligned with the gap 24 of the grade side virtual tie bar 22, but it will be seen that in some preferred embodiments, the gap 30 of the cone side virtual tie bar 28 may be offset horizontally, vertically, or both from the gap 24 of the grade side virtual tie bar 22.

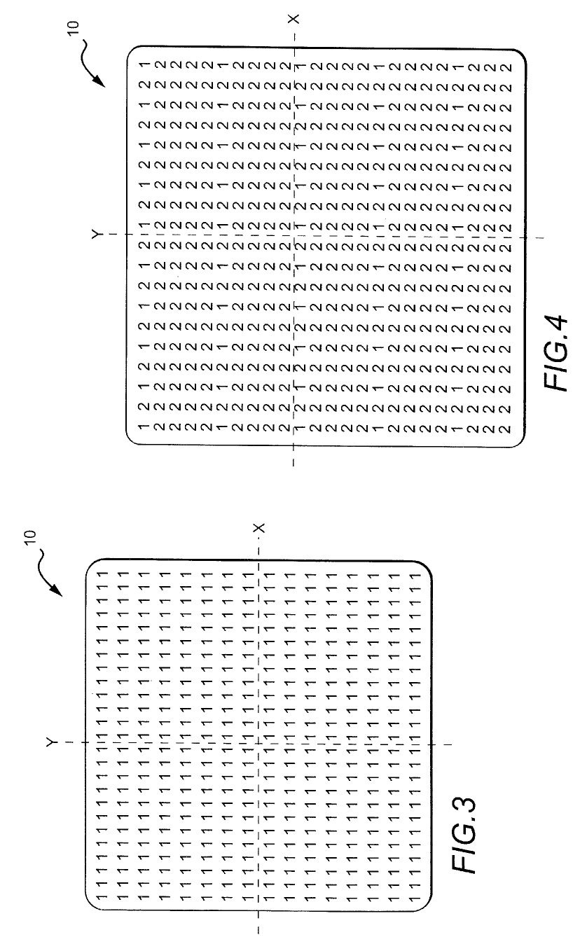

Having explained the five tie bar configurations (1)-(5) found in the various embodiments of the present invention, it is now possible to discuss mask design. Referring now to FIG. 3, there is shown a first embodiment of the GTO concept. It can be seen that the mask 10 includes, by way of convention, an x-axis and a y-axis. A plurality of apertures are found relatively uniformly throughout the mask 10. It is understood that the apertures are designated by a (1) signifying they are of configuration (1) of FIG. 2a. It is further understood that though FIG. 3 shows only a limited number of columns having a limited number of apertures each, in actuality there are hundreds of columns each having hundreds of apertures. Thus, FIG. 3 represents a mask 10 defining hundreds of thousands of apertures having configuration (1) of FIG. 2a.

FIG. 4 shows another embodiment of the mask 10 of the present invention. The mask 10 of FIG. 4 is made up of a combination of tie bar configurations (1) and (2) of FIGS. 2a and 2b. Preferably, the combination is arranged such that a grade side actual tie bar 20 of configuration (1) alternates with one or more grade side virtual tie bars 22 of configuration (2), as shown. More preferably, there are between five and twenty five grade side virtual tie bars 22 or configuration (2) between each grade side actual tie bar 20 of configuration (1). There are no cone side actual tie bars 26 or cone side virtual tie bars 28 in this embodiment.

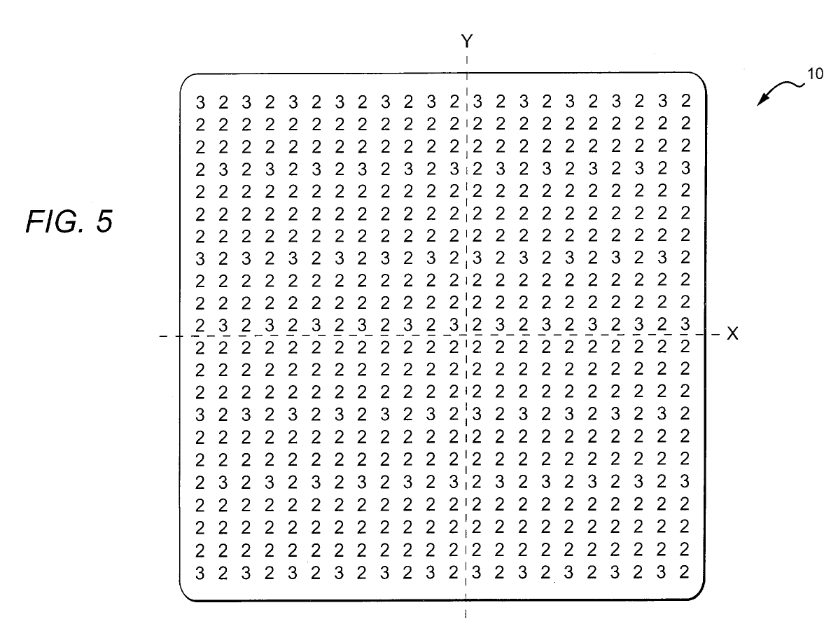

FIG. 5 shows a third embodiment of the mask 10, which is similar to the second embodiment shown in FIG. 4. A uniformly distributed combination pattern of two different configurations is provided. However, in FIG. 5, those areas that have grade side actual tie bars 20 also have cone side actual tie bars 26. Thus, configuration (3) has replaced configuration (1) in the embodiment of FIG. 5. Thus, the mask 10 of FIG. 5 has more strength and rigidity than the mask 10 mapped in FIG. 4.

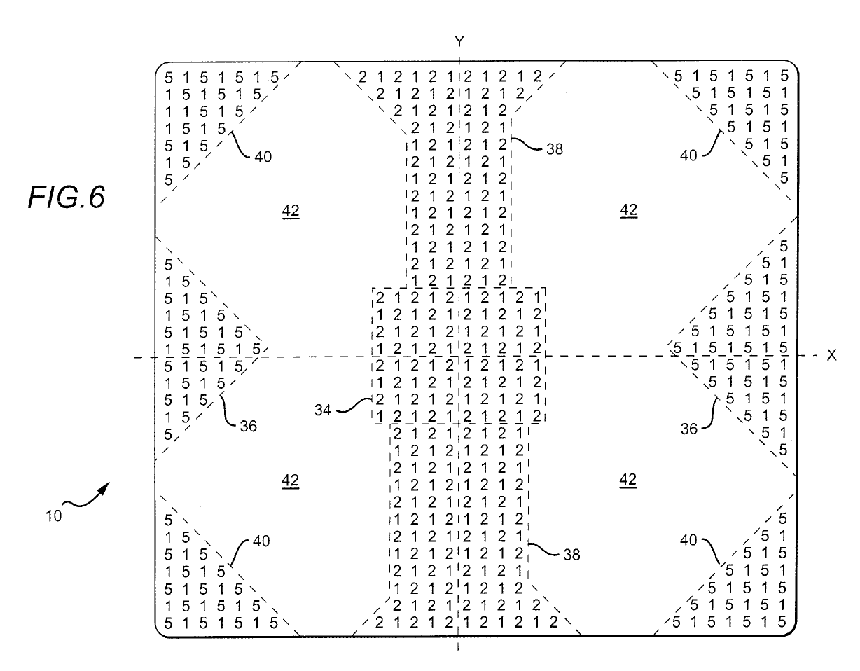

FIG. 6 shows a fourth preferred embodiment of mask 10. The numbers signifying the configuration from FIG. 2 are drawn smaller in order to more accurately map the various zones of the mask 10. Inference is not being made that the apertures are arranged more densely or that the mask is larger than those shown in FIGS. 3-5. The pattern of the mask 10 includes a center zone 34, a pair of zones 36 located at the outer edges of the x-axis, a pair of zones 38 located along the y-axis, and four diagonal zones 40 located in the corners of the mask.

The center zone 34 and the zones 38 located near the y-axis include configurations (1) and (2) from FIG. 2. Thus, on the grade side of the mask 10 in these areas, there are grade side actual tie bars 20 and grade side virtual tie bars 22 that separate the various apertures 18. On the cone side of the mask 10 in these areas, there are no cone side tie bars, just a plurality of troughs 16.

The zones 36 along the x-axis and the diagonal zones 40 include configurations (1) and (5) from FIG. 2. On the grade side of the mask 10 in these areas, there are grade side actual tie bars 20 and grade side virtual tie bars 22. On the cone side of the mask 10, there are no cone side tie bars that correspond to the grade side actual tie bars 20. However, there are cone side virtual tie bars 28 that correspond to the grade side virtual tie bars 22.

Noticeably, this GGTO embodiment includes transition zones 42 between the aforementioned zones 34, 36, 38, and 40. The transition zones 42 are made up of all three of the different configurations (1), (2) and (5) found on the mask 10. However, the concentration of configurations (2) and (5) change depending on location. For example, though the transitions zones 42 are shown as being empty for purposes of clarity, the areas in zones 42 that are near zones 34 and 38 have a high concentration of configuration (2) and a smaller concentration of configuration (5). These concentrations gradually reverse in zones 42 near zones 36 and 40 such that the concentration of configuration (5) is high and the concentration of configuration (2) is small. Configuration (1) remains relatively constant through the entire mask 10 as the grade side actual tie bars 20 of configuration (1) are necessary to provide structural integrity to the mask 10.

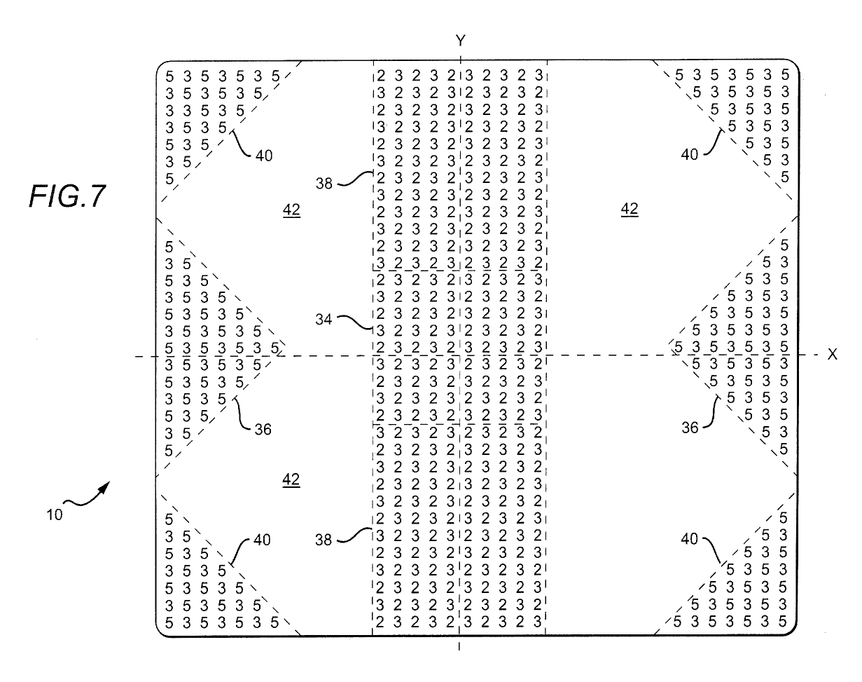

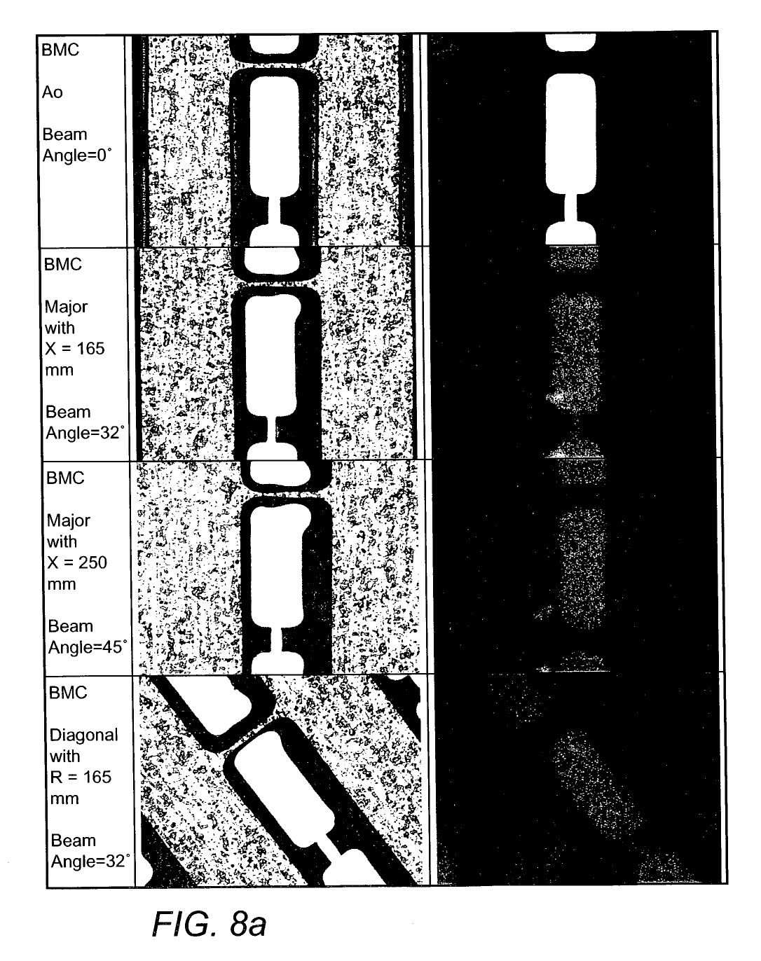

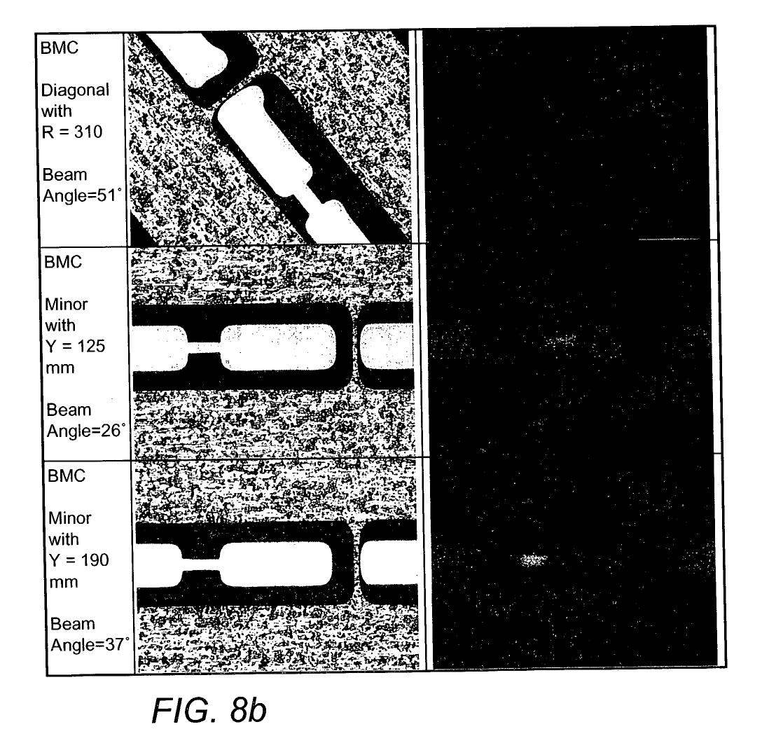

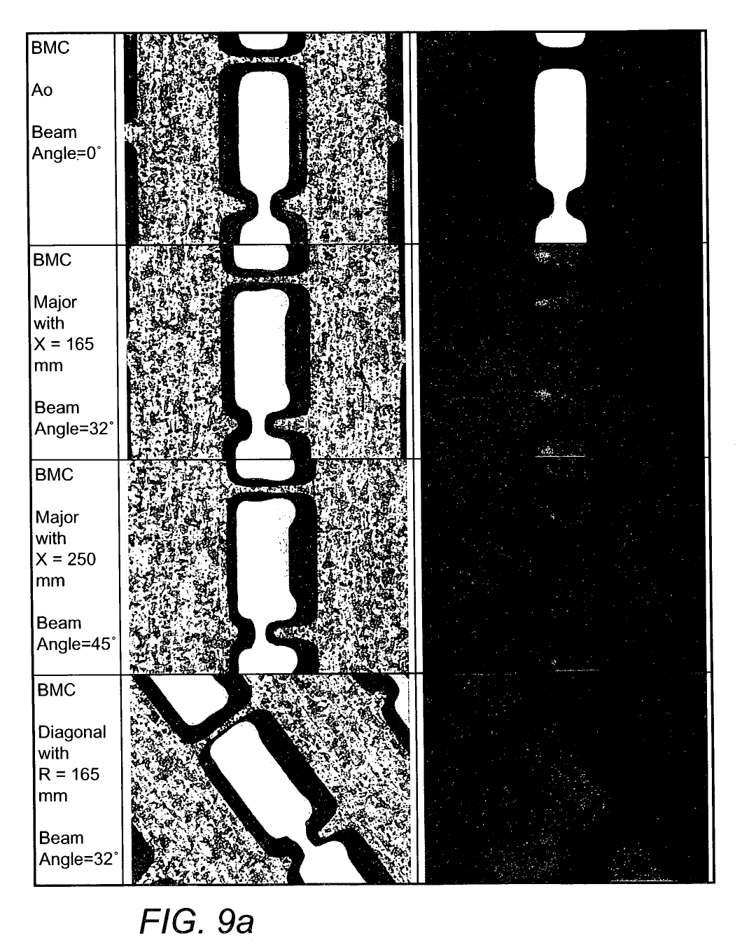

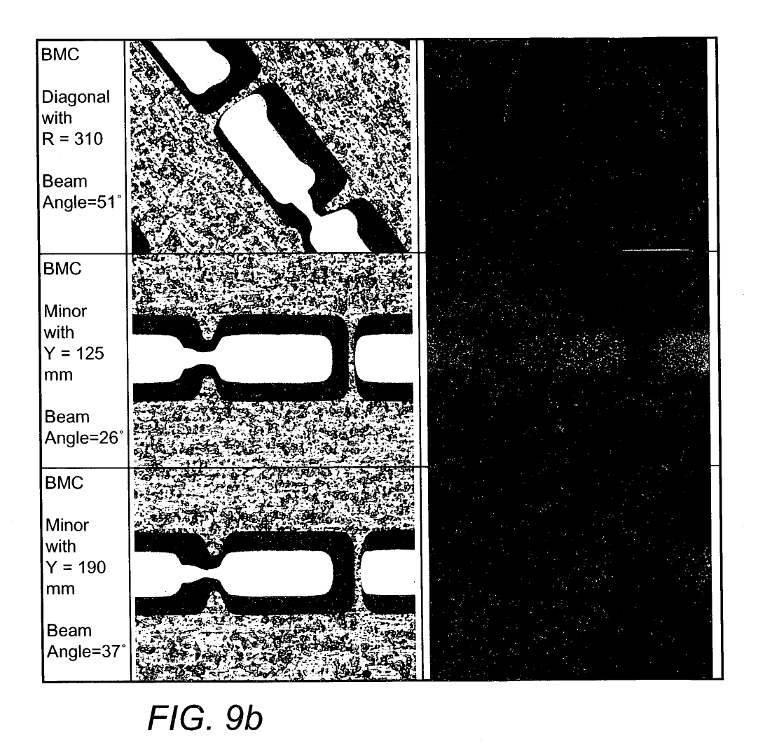

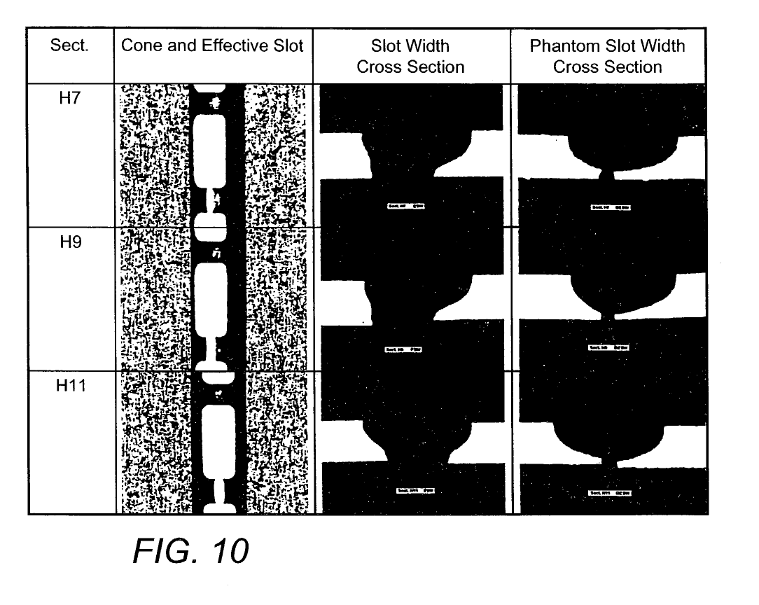

FIG. 7 shows an embodiment of mask 10 that is essentially the same as that shown in FIG. 6 with one difference: those areas that have grade side actual tie bars 20 also have cone side actual tie bars 26. The cone side actual tie bars 26 may improve the overall strength of the mask and reduce damage during handling. In terms of the convention of FIG. 2, configuration (1) has been replaced with configuration (3).

Thus, the center zone 34 and the zones 38 located near the y-axis include configurations (2) and (3) from FIG. 2. On the grade side of the mask 10 in these areas, there are grade side actual tie bars 20 and grade side virtual tie bars 22 that separate the various apertures 18. On the cone side of the mask 10 in these areas, there are no cone side tie bars that correspond to the grade side virtual tie bars 22, but there are cone side actual tie bars 26 that correspond to the grade side actual tie bars 20. The zones 26 along the x-axis and the diagonal zones 40 include configurations (3) and (5) from FIG. 2. On the grade side of the mask 10 in these areas, there are grade side actual tie bars 20 and grade side virtual tie bars 22. On the cone side of the mask 10, there are cone side actual tie bars 26 that correspond to the grade side actual tie bars 20, and cone side virtual tie bars 28 that correspond to the grade side virtual tie bars 22.

There are also transition zones 42 between the aforementioned zones 34, 36, 38, and 40. The transition zones 42 are made up of all three of the different configurations (2), (3) and (5) found on the mask 10. The concentration of configurations (2) and (5) change depending on location in the same manner as the embodiment shown in FIG. 6. Again, the transitions zones 42 are shown as being empty for purposes of clarity, and the areas in zones 42 that are near zones 34 and 38 have a high concentration of configuration (2) and a smaller concentration of configuration (5). These concentrations gradually reverse in zones 42 near zones 36 and 40 such that the concentration of configuration (5) is high and the concentration of configuration (2) is small. Configuration (3) remains relatively constant through the entire mask 10 as the grade side actual tie bars 20, reinforced with the cone side actual tie bars 26 of configuration (3) are necessary to provide structural integrity to the mask 10.

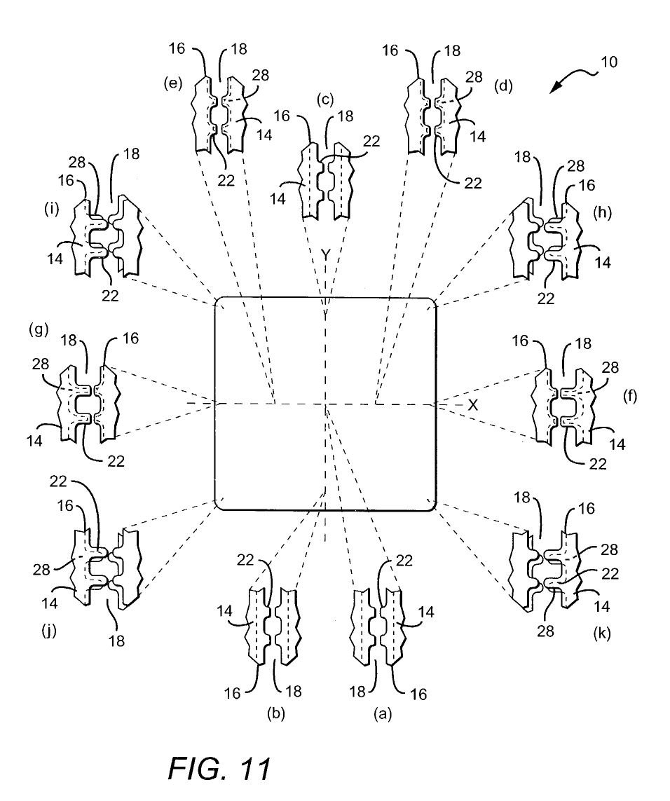

FIG. 11 shows another preferred embodiment exhibiting the GGTO concept of the present invention. Rather than the occurrence of screen side virtual tie bars transitioning from sparse to densely populated as the distance from the center of the mask increases, in this embodiment, the size and shape of the cone side virtual tie bars 28 transition from essentially non-existent in the center of the mask to relatively prominent toward the extreme x-axis areas and the diagonal corners. Notably, the offsets between the grade side virtual tie bars 22 and the cone side virtual tie bars 28 increase as the outer periphery of the mask 10 is reached. A different convention is used in FIG. 11 to describe the mask 10 than that of FIGS. 3 through 7 because it is important to show the changing shape and offset of the screen side virtual tie bars 28.

Specifically, FIG. 11 is drawn from the perspective of the electron gun to show the purpose of the offsets between the grade side virtual tie bars 22 and the cone side virtual tie bars 28. Thus, the gun side 14 of the mask is shown while features on the screen side 12 are shown in phantom lines. The various aperture shapes are detailed in enlarged views (a) through (k), which are generally representative of the other apertures in the areas of the mask 10 from which they project. The enlarged views (a) through (k) all show a fully shaped aperture 18 surrounded by grade side virtual tie bars 22 and two partial views of adjacent apertures 18. Details on the cone side 12 are shown in phantom where hidden and the features that show through the apertures 18 are shown in regular lines.

Enlarged view (a) is representative of the apertures 18 found in the center of the mask 10. The grade side virtual tie bars 22 are formed opposite a cone side trough 16 but there are no corresponding cone side virtual tie bars. Notably, the individual arms of the grade side virtual tie bars 22 are approximately the same size.

Moving outward from the center vertically, views (b) and (c) are representative of the apertures 18 found generally along the y-axis of the mask 10. Because the cone side trough 16 runs vertically, electron beams that bend from the center in a vertical direction do not require clipping. Therefore, it is optimal to maintain an absence of cone side virtual tie bars along the y-axis. Thus, the shape of the apertures 18 do not vary along the y-axis.

However, moving outward from the center horizontally, the electron beam begins to encounter interference with the side walls of the virtual tie bars. Thus, looking first at views (d) and (e), it can be seen that arms of the grade side virtual tie bars 22 are beginning to grow longer on the outer side of the aperture 18 and shorter on the side of the aperture toward the center of the mask 10. Additionally, clipping control is provided by way of cone side virtual tie bars 28. Notably, the cone side virtual tie bars 28 are still relatively small and are more prominent on the outside of the aperture 18 than toward the center of the mask 10. Also, the trough 16 and the cone side virtual tie bars 28 are becoming slightly offset from the grade side features toward the outside of the mask 10.

Transition in this manner continues and becomes most prevalent at the outer edges of the mask 10. Looking now at views (f) and (g), it can be seen that the outer arms of the grade side virtual tie bars 22 are significantly larger than the opposing inner arms. Also, the corresponding cone side virtual tie bars 28 are larger and more offset toward the outside of the mask than those of views (d) and (e) due to the increased angle of beam travel. Because the features of views (f) and (g) are still located relatively close to the x-axis, there is no vertical offset between the grade side features and the cone side features.

Transition away from the x-axis toward the four corners of the mask 10 is marked by vertical offset between the grade side features and the cone side features, as shown in views (h), (i), (j), and (k). The size and shape of the virtual tie bars 22 and 28 is approximately the same as in views (f) and (g), however the cone side virtual tie bars 28 are offset (shown exaggerated in the views for clarity) toward the outside of the mask 10 in both the horizontal and the vertical directions, thereby allowing for the angle of travel of the electron beam.

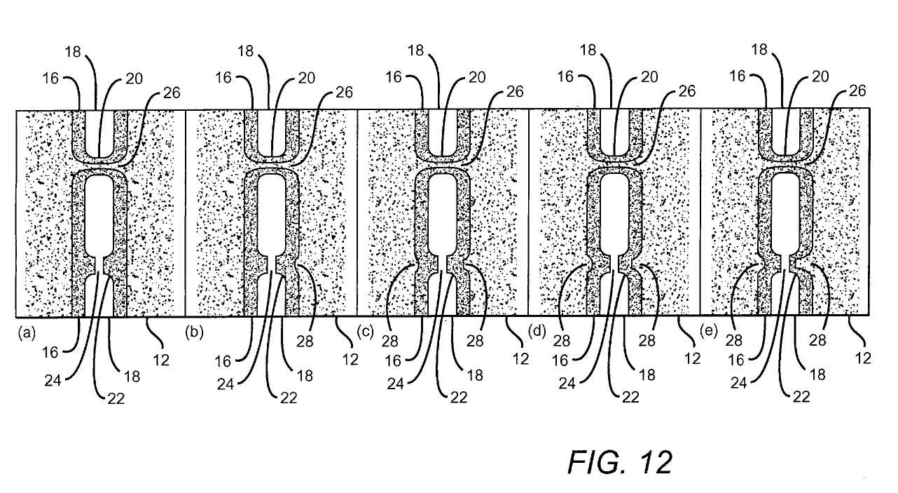

FIG. 12 is a series of photographs (a) through (e) taken from various points on a mask 10 of the embodiment of FIG. 11 from the cone side 12 of the mask 10. Each photograph includes a grade side actual tie bar 20, a corresponding cone side actual tie bar 26, a grade side virtual tie bar 22 defining a gap 24, three apertures 18 and a trough 16.

The series begins with photograph (a), taken from the center of the mask 10. With the exception of the cone side actual tie bar 26, the trough 16 is uninterrupted with cone side virtual tie bars. Notably, the arms of the grade side virtual tie bar are of equal size such that the gap 24 is centered within the aperture 18.

The series progresses outwardly from the center of the mask 10 with photograph (b). A cone side virtual tie bar 28 begins to appear on the outer side of the aperture 18. Also, the outer arm of the grade side virtual tie bar 22 is just slightly longer than the opposite arm on the inner side of the aperture 18 toward the center of the mask 10.

Next, photograph (c) was taken at a point along the x-axis of the mask 10 approximately midway between the center of the mask and the outer right edge as viewed from the cone side 12. The outer arm of the cone side virtual tie bar 28 is becoming more prominent while an inner arm of the cone side virtual tie bar 28 is just beginning to appear. Similarly, the outer arm of the grade side virtual tie bar 22 is growing while the inner arm is shrinking as a lateral offset begins to appear.

Photograph (d) was taken at a point even closer to the right edge of the mask 10 on the cone side 12. Both arms of the cone side virtual tie bar 28 are now readily apparent, with the outer arm being significantly larger than the inner arm. Likewise, the inner arm of the grade side virtual tie bar 22 is much shorter than the outer arm of the grade side virtual tie bar 22. This accentuates a noticeable lateral offset with the gap 24 well left of center of the aperture 18.

Photograph (e) was taken at the right edge of the mask 10 on the cone side 12. Prominent are the cone side virtual tie bar 28 and the lateral offset between the various features on the cone side 12 and the features on the grade side 14. The well formed outer arm of the cone side virtual tie bar 28 provides significant clipping to angled electron beam that would otherwise distort the features of the apertures 18.

what is claimed is:

1. A mask comprising:
a sheet having a grade side and a cone side;
a plurality of troughs extending partially through the sheet and defined by the cone side;
a plurality of apertures defined by the grade side extending from the troughs through the grade side;
wherein at least some of said apertures are separated from adjacent apertures by grade side actual tie bars;
wherein at least some of said apertures are separated from adjacent apertures by grade side virtual tie bars; and,
wherein at least one of the grade side virtual tie bars has no corresponding cone side virtual tie bars.

2. The mask of claim 1 wherein at least some of said grade side actual tie bars extend up through the trough to the cone side of the mask, thereby forming cone side actual tie bars on the grade side actual tie bars.

3. The mask of claim 1 further comprising cone side virtual tie bars extending from at least some of said grade side actual tie bars to the cone side of the mask.

4. The mask of claim 1 further comprising cone side virtual tie bars extending from at least some of said grade side virtual tie bars to the cone side of the mask.

5. The mask of claim 1 wherein the apertures are separated by an alternating pattern of a predetermined number of grade side virtual tie bars and a predetermined number of grade side actual tie bars.

6. The mask of claim 5 wherein the predetermined number of grade side virtual tie bars is greater than 4 and less than 25 and the predetermined number of grade side actual tie bars is greater than zero and less than 5.

7. The mask of claim 5 further comprising cone side actual tie bars extending toward the cone side from the grade side actual tie bars.

8. The mask of claim 1 wherein the mask is generally rectangular and further comprises:
a center zone covering an area near the center of the mask;
an outer edge;
a pair of y-axis zones covering areas above and below the center zone;
a pair of x-axis zones covering extreme areas to the left and right of the center zone;
four diagonal transition zones covering areas not covered by the center zone, the y-axis zones and the x-axis zones;
wherein:
wherein there are no cone side virtual tie bars that correspond with the grade side virtual tie bars in the center zone and in the y-axis zones; and,
wherein there are cone side virtual tie bars that correspond with the grade side virtual tie bars in the x-axis zones and in the transitional zones.

9. The mask of claim 8 wherein the cone side virtual tie bars near the outer edge of the mask are larger than cone side virtual tie bars relatively farther from the outer edge of the mask.

10. The mask of claim 8 wherein the cone side virtual tie bars comprise an outer arm and an inner arm and a gap defined between the outer arm and the inner arm, and wherein the outer arm is larger than the inner arm.

11. The mask of claim 8 wherein the cone side virtual tie bars are closer to the outer edge of the mask than the corresponding grade side virtual tie bars.

12. The mask of claim 8 further comprising at least some cone side actual tie bars extending toward the cone side from the grade side actual tie bars.

13. The mask of claim 1 wherein the mask is generally rectangular and further comprises:
a center zone covering an area near the center of the mask;
a pair of y-axis zones covering areas above and below the center zone;
a pair of x-axis zones covering extreme areas to the left and right of the center zone;
four diagonal zones covering areas in the four corners of the mask;
transition zones in all areas of the mask that are not covered by any of the center zone, y-axis zones, x-axis zones, or the diagonal zones;
wherein:
the apertures located in the center zone and the y-axis zones are alternatingly separated by grade side actual tie bars and grade side virtual tie bars having no corresponding cone side tie bars;
the apertures located in the x-axis zones and the diagonal zones are alternatingly separated by grade side actual tie bars and grade side virtual tie bars having corresponding cone side virtual tie bars; and,
the apertures located in the transition zones gradually transition from being alternatingly separated by grade side actual tie bars and grade side virtual tie bars having no corresponding cone side tie bars near the center zones and the y-axis zones to being alternatingly separated by grade side actual tie bars and grade side virtual tie bars having corresponding cone side virtual tie bars near the x-axis zones and the diagonal zones.

14. The mask of claim 1 wherein the mask is generally rectangular and further comprises:
a center zone covering an area near the center of the mask;
a pair of y-axis zones covering areas above and below the center zone;
a pair of x-axis zones covering extreme areas to the left and right of the center zone;
four diagonal zones covering areas in the four corners of the mask;
transition zones in all areas of the mask that are not covered by any of the center zone, y-axis zones, x-axis zones, or the diagonal zones;
wherein:
the apertures located in the center zone and the y-axis zones are alternatingly separated by grade side actual tie bars having corresponding cone side actual tie bars and grade side virtual tie bars having no corresponding cone side tie bars;
the apertures located in the x-axis zones and the diagonal zones are alternatingly separated by grade side actual tie bars having corresponding cone side actual tie bars and grade side virtual tie bars having corresponding cone side virtual tie bars; and,
the apertures located in the transition zones gradually transition from being alternatingly separated by grade side actual tie bars having corresponding cone side actual tie bars and grade side virtual tie bars having no corresponding cone side tie bars near the center zones and the y-axis zones to being alternatingly separated by grade side actual tie bars having corresponding cone side actual tie bars and grade side virtual tie bars having corresponding cone side virtual tie bars near the x-axis zones and the diagonal zones.

15. A method of designing a mask usable to direct an electron beam comprising:
placing a plurality of apertures in the mask at predetermined locations;
separating at least some of the apertures with a regular pattern of grade side actual tie bars in order to provide structural integrity to the mask;
separating the remaining apertures with grade side virtual tie bars at least one of said grade side virtual tie bars having no corresponding cone side tie bar.

16. The method of claim 15 further comprising separating at least some of the apertures with cone side actual tie bars that correspond to the grade side actual tie bars.

17. The method of claim 15 further comprising:
identifying clipping zones on said mask where clipping is desired;
placing cone side virtual tie bars in the clipping zones that correspond with the grade side virtual tie bars in the clipping zones.

18. The method of claim 17 further comprising:
identifying non-clipping zones on said mask where clipping is not desired;
designating areas between the clipping zones and non-clipping zones as transition zones;
placing no cone side virtual tie bars that correspond with the grade side virtual tie bars in the non-clipping zones;
placing a varying concentration of cone side virtual tie bars that correspond with grade side virtual tie bars in the transition zones such that the concentration of cone side virtual tie bars is low in close proximity to the non-clipping zones and gradually transitions to a high concentration of cone side virtual tie bars in close proximity to the clipping zones.

19. The method of claim 18 further comprising placing cone side actual tie bars in correspondence with the grade side actual tie bars throughout the mask.

20. The method of claim 17 further comprising:
identifying non-clipping zones on said mask where clipping is not desired;
designating areas between the clipping zones and non-clipping zones as transition zones;
leaving the grade side virtual tie bars in the non-clipping zones free of corresponding cone side virtual tie bars;
placing a cone side virtual tie bars that correspond with grade side virtual tie bars in the transition zones such that the size of the cone side virtual tie bars is small in close proximity to the non-clipping zones and gradually transitions to relatively large cone side virtual tie bars in close proximity to the clipping zones.

21. A mask useable to direct an electron beam comprising:
a sheet having a cone side and a grade side;
a regular pattern of elongated apertures formed in the sheet and separated from longitudinally adjacent apertures with tie bars;
wherein some of the tie bars on the grade side define gaps therein, the tie bars defining gaps being distributed across the mask in a regular pattern, and at least one of the tie bars defining gaps being free of corresponding tie bars on the cone side.

22. The mask of claim 21 wherein the apertures are larger on the cone side of the mask than on the grade side of the mask.

23. The mask of claim 22 further comprising a plurality of troughs formed in the cone side of the mask and aligned with the longitudinal direction of the apertures, the troughs located such that the apertures are formed in the troughs, the troughs accounting for the larger size of the apertures in on the cone side of the mask.

24. The mask of claim 23 wherein the tie bars do not extend into the trough.

25. The mask of claim 23 wherein the tie bars extend into the trough.

26. The mask of claim 23 wherein at least some of the tie bars extend into the trough.
